(19) United States
(12) Patent Application Publication
(10) Pub. No.: US 2026/0005161 A1
(43) Pub. Date: Jan. 1, 2026

(54) LITHOGRAPHIC SEAM IMPLEMENTATION FOR ACTIVE INTERCONNECT ROUTING ACROSS MULTIPLE RETICLE FIELDS

(71) Applicant: Intel Corporation, Santa Clara, CA (US)

(72) Inventors: Keith Zawadzki, Portland, OR (US); Nathan McCorkle, Banks, OR (US); Somnath Chakraborty, Hillsboro, OR (US); Aalay Kapadia, Hillsboro, OR (US); Kim-Anh Sherman, Phoenix, AZ (US); Kirsten Thompson, Hillsboro, OR (US); Apoorva Jain, Hillsboro, OR (US); Shakul Tandon, Portland, OR (US)

(73) Assignee: Intel Corporation, Santa Clara, CA (US)

(21) Appl. No.: 18/759,030

(22) Filed: Jun. 28, 2024

(51) Int. Cl. H01L 23/58; G03F 7/00; G03F 9/00; H01L 21/48; H01L 21/66; H01L 23/498; H01L 23/544

(52) U.S. Cl. CPC H01L 23/585; G03F 7/70466; G03F 9/70; H01L 21/4857; H01L 22/12; H01L 22/32; H01L 23/49822; H01L 23/544

(57) ABSTRACT

Integrated circuit dies, interposers, systems, and methods are described related to implementing seams between fields exposed using different lithographic exposures. First and second metallization stack regions or fields each implement signal and/or power routing and are separated by a seam therebetween. The seam includes conductive features that span the seam and interconnect the metallization stack regions. A test feature surrounds the metallization stack regions and includes metallization portions that also span the seams. The test feature is within a seal ring and, through electrical testing, validates the conductive features that span the seam.

### BACKGROUND

As the integrated circuit industry continues to produce ever more advanced devices for use in various electronic products, current die and interposer sizes are limited by the size of a standard lithographic reticle that results in one patterned field on the wafer. For example, the features of a die or interposer may be fabricated using a single lithographic field that corresponds to a single lithographic exposure using a single reticle. However, there is an increasing desire to fabricate dies or interposers that include multiple (e.g., two or more) adjacent lithographic fields. Such fields may be exposed using different reticles or the same reticle. In either context, there is a desire to interconnect features of the fields. For example, metal lines that extend between adjacent fields are needed for interconnection, routing, etc. The interconnection of such features is achieved through reticle stitching (or exposure stitching), where features from adjacent fields/reticles are adjoined or stitched together to provide, after exposure and other fabrication processing, metallization features that extend across the boundary between adjacent fields on the wafer.

Furthermore, advanced design has moved towards disaggregated chiplets or tiles placed on a large interposer die to form a multi-chip package (MCP). Scaling performance and computation in the Artificial Intelligence (AI) era has further pushed the demand for larger interposers beyond a single reticle field size. As a result, various techniques are being used to deliver more chip real-estate inside an MCP and in other contexts. One solution is to grow the size of a die and/or interposer beyond a reticle field size as discussed above.

Such reticle stitching processing faces continued difficulties due to lithographic limitations inclusive of placement error (registration error), distortion, and others. It is with respect to these and other considerations that the present improvements have been needed. Such improvements may become critical as the need to provide larger dies and/or interposers having more complicated features using reticle stitching is necessary to support ever more sophisticated electronics systems and complexes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates an example monolithic interposer including field regions interconnected by cross-seam line features, and a test structure and a seal ring surrounding the field regions fabricated by reticle stitching;

FIG. 2 illustrates an example lithographic patterning context for deploying reticle stitching to form line features, test features, and seal ring features across a seam between fields;

FIG. 3 illustrates exemplary monolithic interposer including metallization regions interconnected by cross-seam metallization features, and a test metallization structure and a seal ring surrounding the metallization field regions;

FIG. 4A illustrates a cross-sectional side view of a portion of a metallization region of the interposer of FIG. 3;

FIG. 4B illustrates a cross-sectional side view of a portion of conductive features crossing a seam of the interposer of FIG. 3;

FIG. 5 illustrates a cross-sectional side view of a portion of a metallization test feature of the interposer of FIG. 3;

FIG. 6 illustrates a cross-sectional side view of a portion of a seal ring of the interposer of FIG. 3;

FIG. 7 illustrates an exemplary metallization test feature including contact pads and test circuitry;

FIG. 8 illustrates an exemplary lithography block including a number of conductive features deployed within metallization regions of the interposer of FIG. 3;

FIG. 9 is a flow diagram illustrating an example process for fabricating an interposer or integrated circuit device having field regions interconnected by cross-seam line features, and a test structure and a seal ring surrounding the field regions fabricated by reticle stitching;

FIGS. 10A, 10B, 10C, 10D, 10E, and 10F are views of example interposer or integrated circuit devices as particular fabrication operations of the process of FIG. 9 are performed;

FIG. 11 illustrates an example packaged multichip composite device including an interposer having field regions interconnected by cross-seam line features, and a test structure and a seal ring surrounding the field regions fabricated by reticle stitching;

FIG. 12 is a cross-sectional top-down view of the packaged multichip composite device of FIG. 11;

FIG. 13 illustrates exemplary systems employing an IC assembly including a multichip composite device having a stitched interposer or die having a test feature and a seal ring surrounding an interior of the interposer or die; and

FIG. 14 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Apparatuses, integrated circuit dies, interposers, multi-chip packages or systems, and techniques are described herein related to implementing semiconductor designs with metallization features that span lithographic seams between adjacent fields including deployment of a test structure to verify the metallization features, a seal ring to enclose the test structure and resultant monolithic die or interposer, and within field lithography blocks for improved lithography alignment and exposure.

As discussed, there is an increasing need to fabricate monolithic dies or interposers that include multiple (e.g., two or more) adjacent lithographic fields. This provides for advantageously larger dies or interposers for implementation in a variety of context such as multi-chip package (MCP) contexts. Such techniques may be characterized as die-to-die reticle stitching or exposure stitching. In such contexts, there are difficulties in stitching across the fields due to lithographic limitations including registration error, distortion, and others. The techniques and features discussed herein provide a semiconductor design lithographic scam implementation methodology for active interconnect wire routing across a plurality of reticle fields. For example, the discussed techniques create available active power and signal wires across the reticle seams to deliver multi-reticle field die sizes.

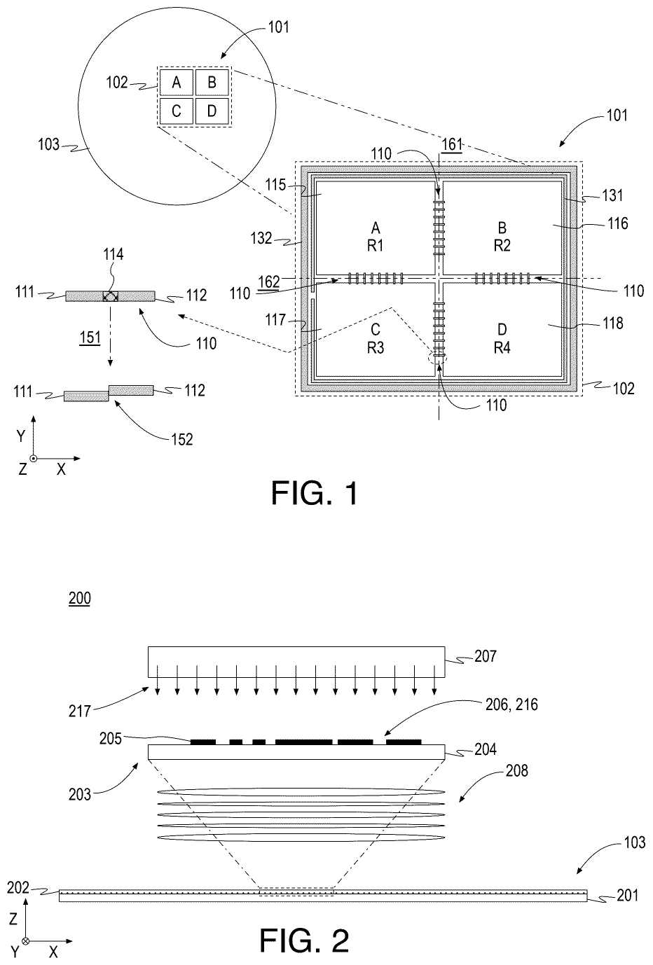

FIG. 1 illustrates an example monolithic interposer 101 including field regions interconnected by cross-seam line features, and a test structure and a seal ring surrounding the field regions fabricated by reticle stitching, arranged in accordance with at least some implementations of the present disclosure. As shown, interposer 101 may be singulated from substrate wafer 103 using scribe cuts 102 that surround interposer 101 but do not intersect between fields 115, 116, 117, 118 (also labeled as A, B, C, D) of interposer 101 such that fields 115, 116, 117, 118 correspond to areas or regions patterned using separate lithography exposures. Such exposures may be by different reticles R1, R2, R3, R4 although the same reticles may be used if repeat patterns are deployed. Fields 115, 116, 117, 118 may also be characterized as regions or tiles. As used herein, the term interposer 101 is inclusive of interposers that provide signal and power routing. Although described with respect to interposer 101, the discussed techniques may also be used to form a multi-field IC die having devices such as transistors, resistors, capacitors, etc., or the like. In some embodiments, interposer 101 is a host substrate or a host die including a metallization pattern that provides routing to IC dies that are mounted to interposer 101, as discussed further herein below. In some embodiments, interposer 101 is an IC die includes a device layer underlying the metallization pattern such that the device layer includes transistors. For example, interposer 101 or an IC die may be deployed in any context where greater surface area is needed relative to that provided by a single field exposure.

Fields 115, 116, 117, 118 are patterned in separate lithography exposures that may include reticle stitched features or lines 110 (e.g., line features, metal lines, or wires) that are to be connected across fields 115, 116, 117, 118. As used herein, the term reticle stitched feature or line indicates a feature or line that crosses over between reticles and exposure fields such that one portion or region is from a first reticle and exposure field and a second portion or regions from a second reticle and exposure field. Notably, after separate patterning (e.g., lithography), the features of fields 115, 116, 117, 118 are fabricated in the same operations (e.g., etch, deposition, planarization, etc.) and therefore are co-planar in the x-y plane and include the same material compositions. For example, a metallization layer of interposer 101 includes co-planar metallization features of fields 115, 116, 117, 118 and metallization features of lines 110 to form an integrated metallization layer of interposer 101. Thereby, lines 110 provide an integral part of interposer 101 so signal and/or power routing across interposer 101 is at least partially provided by lines 110. Herein, lithographic patterned features (i.e., patterns formed in resist or an underlying dielectric) and the resultant features (i.e., a metal line, metal via, or other electrical structure) are described substantially interchangeably.

In some embodiments, lines 110 (i.e., the reticle pattern, the resultant wafer level pattern, or the resultant feature pattern) are provided as a library of power and/or signal interconnect design cells that may be selectable in designing interposer 101. For example, the pattern of lines 110 may be defined by a number of repeating selectable cells that are then defined on interposer 101 and the reticle(s) used to pattern them. At the reticle level, the corresponding reticle pattern may include serifs, line overlaps, and other reticle patterns that improve the wafer level patterning of lines 110. As discussed, such reticle level patterns may be repeated and advantageously selected as cells for improved design efficiency. For example, a design kit may include the cell patterns of lines 110, which allows design of an entire lithographic reticle seams (e.g., using repeated cell patterns) with pre-set interconnect seam wires to form a fully routed multi-reticle field inside a single interposer 101. Such pre-set seam wires facilitate advanced placement and routing of the ultimate metallization (e.g., wires) of lines 110 during the design phase and may be advantageously designed for improved lithography processing based on the nature of the double exposure in seams 161, 162 (seam regions or reticle seam regions) between adjacent ones of fields 115, 116, 117, 118. The techniques discussed herein provide for active seam wires to route across the lithographic seams in a plurality of reticle fields using an efficient design methodology, to monitor the integrity of wires across the seams, and to minimize lithographic optical proximity correction (OPC) during mask creation.

For example, a portion of each of lines 110 includes a continuous portion or region 111 from exposure of one of fields 115, 116, 117, 118 and a continuous portion or region 112 from exposure of another adjacent one of fields 115, 116, 117, 118 such that region 111 and region 112 overlap or are abutted to one another to provide a resultant line 110. The terms portion and region are used interchangeably herein. The term continuous with respect to a region or portion indicates the region or portion is uninterrupted. The term contiguous with respect to multiple regions or portions indicates the regions or portions are in contact with one another along a surface or edge and may thereby form a continuous electrical feature. A continuous region having a width across a particular length indicates the region is uninterrupted in the area defined by the width and length. As shown, each of lines 110 may include a merged portion or region 114 that is defined by both exposures, however, regions 111, 112 may also abut one another. As used herein, the term merged portion or region indicates a resultant region of the overlay of patterns of two regions. In some embodiments, regions 111, 112 have an offset or jog 152 relative to one another due to misalignment 151 in exposing adjacent ones of fields 115, 116, 117, 118. In some embodiments, jog 152 is aligned with the seam 161, 162 that line 110 extends across. For example, lines 110 may be orthogonal to seams 161, 162 and jogs 152 are aligned with seams 161, 162 (and are orthogonal to the length of lines 110).

In forming lines 110 across seam 161 (e.g., a scam in the y-direction) and seam 162 (e.g., a seam in the x-direction) such that seam 162 is orthogonal to seam 161, the discussed misalignment can provide difficulties in forming continuous merged metallization or wires that span seams 161, 162. Such finally formed lines 110 may be fully disconnected or they may be misaligned such that jogs 152 reduce the desired electrical properties of lines below acceptable design limits. For example, using exemplary lines 110 across seam 161, misalignment in the y-direction may cause jog 152 also in the y-direction that provides reduced electrical connection or full disconnect if jog 152 is large enough and/or misalignment in the x-direction may cause full disconnect again if large enough. It is noted that use of merged portion or region 114 (e.g., predefined overlap in across seam 161) can reduce difficulties due to misalignment in the x-direction. However, difficulties in forming lines 110 persist.

As illustrated further herein below, lines 110 may be formed at multiple metallization levels of interposer 101. For example, exposure of fields 115, 116, 117, 118 may be part of a process that forms metallization of fields 115, 116, 117, 118 and lines 110. Above and/or below such metallization, similar processing forms the features of other metallization layers, intervening via layers, and any other device or material layers that require patterning. That is, the metallization of fields 115, 116, 117, 118 and lines 110 may be part of a multi-layer metallization stack, as illustrated further herein below. The discussed fabrication difficulties of lines 110 are evident at each such metallization layer of interposer 101.

As discussed in greater detail herein below, a test metallization feature 131 is provided in interposer 101 to verify and test the fabrication of all such levels of fields 115, 116, 117, 118. Notably, test metallization feature 131 surrounds fields 115, 116, 117, 118, crosses each of seams 161,162 twice and includes metallization portions from each metallization level of the stack used to form interposer 101. For example, each of fields 115, 116, 117, 118 includes a number of stacked metallization layers or levels (i.e., stacked in the z-dimension), with each layer or level having corresponding lines 110, and corresponding portions of test metallization feature 131.

After fabrication of all such metallization levels or layers, test metallization feature 131 may then be contacted at two contacts by pins of a test probe and the electrical characteristics of test metallization feature 131 (e.g., resistance) are tested to validate lines 110 of each level or layer using a single test metallization feature 131. Thereby, test metallization feature 131 provides an efficient test structure to validate all of lines 110 (i.e., those metallizations or wires at each metallization level) using a single test operation. The details of test metallization feature 131 are discussed further herein below.

Furthermore, interposer 101 includes a seal ring 132 that surrounds test metallization feature 131 (and surrounds fields 115, 116, 117, 118). Seal ring 132 also crosses each of seams 161, 162 twice and includes metallization portions from each metallization level of the stack used to form interposer 101. For example, each of fields 115, 116, 117, 118 includes a number of stacked metallization layers or levels (i.e., stacked in the z-dimension), with each layer or level having a portion of seal ring 132. Therefore, each patterning and corresponding processing in the build-up of interposer 101 forms metallization features of fields 115, 116, 117, 118, metallization features of lines 110, metallization features of test metallization feature 131, and metallization features of seal ring 132. These metallization features are patterned and formed together such that they are co-planar in the x-y plane and include the same material compositions. As used herein, the term co-planar indicates the features are in the same plane such that a single plane intersects each of the features. Such co-planarity may also provide for the features to have co-planar top surfaces, co-planar bottom surfaces, and co-planar centerpoints.

The metallization features (i.e., metallization line levels interconnected by vias) of fields 115, 116, 117, 118 include signal and power routing for interposer 101. For example, the signal and power routing may interconnect IC dies mounted to interposer 101 when interposer 101 is deployed as an interposer. The metallization features (i.e., metallization line levels typically not interconnected by vias) of lines 110 include signal and power routing between the corresponding co-planar levels of the metallization features of adjacent fields 115, 116, 117, 118. The metallization features (i.e., metallization line levels interconnected by vias to form a single continuous conductor) of test metallization feature 131 form a multi-level test structure to validate all levels of lines 110. The metallization features (i.e., metallization line levels stacked on metallization lines formed in the via levels) of seal ring 132 form part of a hermetic seal around the internal region of interposer 101.

After fabrication of all such metallization levels or layers, seal ring 132 surrounds the internal portion of interposer 101 (e.g., the regions of fields 115, 116, 117, 118). Along with an underlying substrate layer (e.g., a silicon substrate) and an overlying passivation layer (e.g., a thick nitride), seal ring 132 protects the internal portion of interposer 101 from moisture and other contaminates.

Although illustrated with four fields 115, 116, 117, 118, any number of fields may be merged to form interposer 101. In some embodiments, two fields 115, 116 or fields 115, 118 are merged to form interposer 101. In some embodiments, six, eight, or more fields are merged to form interposer 101. As discussed fabrication of interposer 101 includes repeated build-up by exposure, metallization layer fabrication, dielectric layer formation, and similar processing such that each such level includes independent exposure of fields 115, 116, 117, 118.

FIG. 2 illustrates an example lithographic patterning context 200 for deploying reticle stitching to form line features, test features, and seal ring features across a seam between fields, arranged in accordance with at least some implementations of the present disclosure. In FIG. 2, a light source 207 is used to provide an exposure 217 through a reticle 203. Reticle 203 includes a transparent substrate 204 and a substantially opaque mask 205 providing a pattern 206 or 216 in a transparent substrate 204. For example, depending on the reticle 203 being deployed any pattern 206, 216, etc. corresponding to the pertinent layer being patterned over substrate 201 of wafer 103 may be deployed.

Exposure 217 continues from reticle 203 through optics 208 to expose a photoresist layer 202 on or over substrate 201 (e.g., a substrate wafer). In some embodiments, the resultant exposure generates photoacids that break down the resist polymer of photoresist layer 202, rendering it soluble in a developer solution. Pattern 206 or 216 is transferred from reticle 203 to photoresist layer 202. The pattern features, regions, etc. discussed herein are applicable to either or both of pattern 206 or 216 of reticle 203 and the resultant pattern of photoresist layer 202. Although illustrated with respect to the pattern being in transparent substrate 204 for use in positive photoresist applications, the pattern may be deployed in reflective substrate and/or negative photoresist contexts. For example, the techniques discussed herein are not limited by the lithography context deployed.

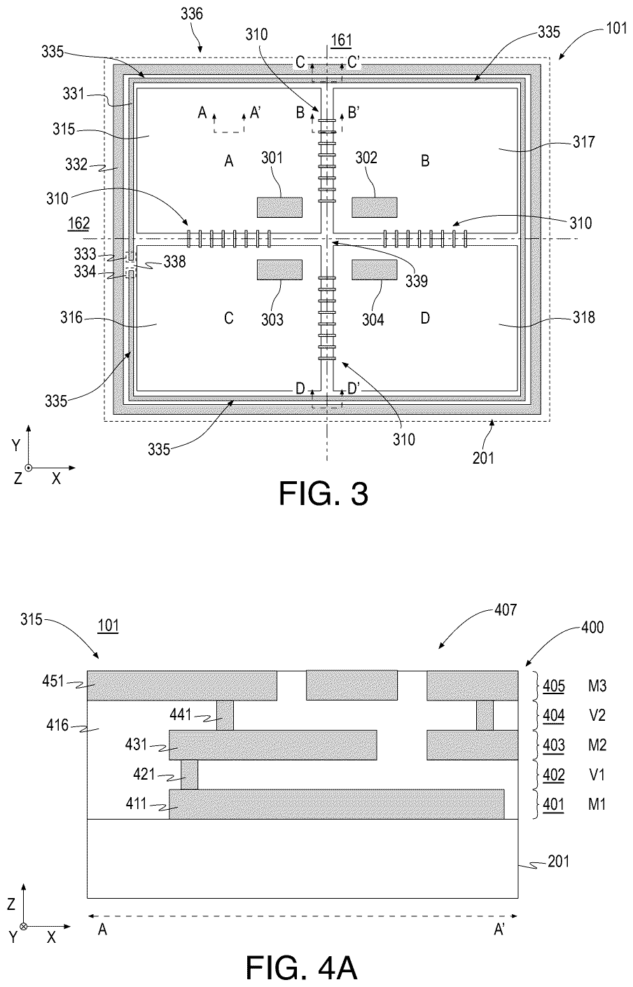

FIG. 3 illustrates exemplary monolithic interposer 101 including metallization regions interconnected by cross-seam metallization features, and a test metallization structure and a seal ring surrounding the metallization field regions, arranged in accordance with at least some implementations of the present disclosure. As discussed, herein, lithographic patterned features and the resultant features are described substantially interchangeably. FIG. 3 illustrates monolithic interposer 101 after metallization of the pattern features illustrated in FIG. 1 and such metallization features may have any corresponding characteristics, which are not repeated for the sake of clarity and brevity.

As shown, interposer 101 may include a number of metallization regions 315, 316, 317, 318 over substrate 201. As discussed, in some contexts an IC die or other semiconductor device may be fabricated, with interposer 101 being illustrated as representative. Substrate 201 may include any suitable material or materials. In some embodiments, substrate 201 is or include a Group IV material (e.g., silicon). In some embodiments, substrate 201 include a substantially monocrystalline material. In some embodiments, substrate 201 includes a buried insulator layer (e.g., SiO₂), for example, of a semiconductor-on-insulator (SOI) substrate and or isolation insulator regions and the like. In some embodiments, substrate 201 includes underlying semiconductor structures such as transistors, capacitors, resistors, or the like in a device layer or layers.

Metallization regions 315, 316, 317, 318, which may be characterized as metallization stacks, include any number of metallization layers (e.g., metal line layers) interconnected vertically by intervening via layers (e.g., metal via layers). In some embodiments, metallization regions 315, 316, 317, 318 include not fewer than two metallization layers interconnected by a via layer. In some embodiments, metallization regions 315, 316, 317, 318 include not fewer than three metallization layers interconnected intervening via layers (e.g., two via layers). However, four, five, or more metallization layers interconnected intervening via layers may be used. Each of metallization regions 315, 316, 317, 318 includes signal and/or power routing using arrays of interconnected lines and vias as is known in the art.

Interposer 101 further includes seams 161, 162 between metallization regions 315, 316, 317, 318. In some embodiments, seam 162 extends between metallization regions 315, 316 and between metallization regions 317, 318 such that an entirety of one border of each of metallization regions 315, 317 is along seam 162 with the borders being aligned in the x-dimension, and an entirety of one border of each of metallization regions 316, 318 is along seam 162 with the borders also being aligned in the x-dimension. Similarly, seam 161 (orthogonal to seam 162) extends between metallization regions 315, 317 and between metallization regions 316, 318 such that an entirety of one border of each of metallization regions 315, 316 is along seam 161 with the borders being aligned in the y-dimension, and an entirety of one border of each of metallization regions 317, 318 is along seam 161 with the borders also being aligned in the y-dimension.

Seams 161, 162 include a number of conductive features 310, which may be characterized as metallization features, metal lines, wires, or the like. Conductive features 310 laterally interconnect metallization regions 315, 316, 317, 318 to provide signal and/or power routing across seams 161, 162. As discussed, metallization regions 315, 316, 317, 318 and conductive features 310 are co-planar over substrate 201 (e.g., in the x-y plane). Such co-planarity is illustrated further herein below.

Also as shown, metallization test feature 331 surrounds metallization regions 315, 316, 317, 318. Metallization test feature 331 includes a first contact 333 separated from a second contact 334 by a dielectric material 338 therebetween. Metallization test feature 331 further includes a continuous conductive route 335 coupling first contact 333 and second contact 334. As shown, first contact 333 and second contact 334 may be part of continuous conductive route 335 (i.e., having a similar width and being co-planar with continuous conductive route 335) such that first contact 333 and second contact 334 are opposite ends of continuous conductive route 335. In some embodiments, first contact 333 and second contact 334 are formed as pads having a greater width in the x-and/or y-dimension for ease of contact by a test pin. In some embodiments, first contact 333 and second contact 334 are formed as bumps that are over (i.e., in the positive z-dimension) a top metallization layer of metallization regions 315, 316, 317, 318.

As shown further herein below, continuous conductive route 335 includes metal portions that are fabricated with metallization layers of metallization regions 315, 316, 317, 318 such that the metallization layers and the metal line portions are co-planar (i.e., in the x-y plane) and formed of the same material(s). Furthermore, as with metallization layers of metallization regions 315, 316, 317, 318, the metal line portions of metallization test feature 331 may be interconnected by metal vias such that the metal line portions and the metal vias form a continuous conductor between first contact 333 and second contact 334. Continuous conductive route 335 thereby also includes conductive features that span each instance of seams 161, 162 (i.e., a north, cast, south, and west instance of the seams) such that any difficulties in fabricating conductive features 310 may be detected by testing metallization test feature 331.

Furthermore, seal ring 332 surrounds metallization test feature 331 and metallization regions 315, 316, 317, 318 and is within a perimeter 336 of interposer 101. Seal ring 332 includes a contiguous stack of metal portions that are each co-planar with the metallization layers of metallization regions 315, 316, 317, 318, conductive features 310 that cross seams 161, 162, the metal line portions of metallization test feature 331, as well as the via layers that interconnect the metallization layers. Notably, seal ring 332 stacks a width of such layers around metallization test feature 331 and metallization regions 315, 316, 317, 318 to provide a hermetic seal for the interior of interposer 101.

Interposer 101 also includes lithography blocks 301, 302, 303, 304 such that each of lithography blocks 301, 302, 303, 304 are proximal a center of interposer 101. Lithography blocks 301, 302, 303, 304 include any suitable alignment marks, fiducial structures, measurement structures or the like that support lithography processing. Exemplary features of lithography blocks 301, 302, 303, 304 are illustrated further herein below. In some embodiments, lithography blocks and similar structures are typically located at a perimeter of the lithographic fields. However, due to the discussed stitching and merger of the fields at center 339 and scams 161, 162 of interposer 101 the lithography blocks and markings are lost proximal to center 339. Notably, other lithography blocks are lost when interposer 101 is segmented from wafer 103. For example, for metallization region 315, lithography block 301 (i.e., the lithography block at the south-east corner of metallization region 315) is moved into metallization region 315 while those lithography blocks at the other three corners (i.e., the lithography blocks at the south-west, north-west, and north-east corners) are lost during segmentation.

As discussed, lithography blocks 301, 302, 303, 304 include any suitable alignment marks, fiducial structures, measurement structures or the like that support lithography processing. In some embodiments, lithography blocks 301, 302, 303, 304 include a fiducial structure within corresponding ones of metallization regions 315, 316, 317, 318 such that each fiducial structure includes a number or conductive features isolated from metallization regions 315, 316, 317, 318. As discussed, lithography blocks 301, 302, 303, 304 and the included fiducial structure is proximal seams 161, 162 relative to a center of metallization regions 315, 316, 317, 318 (i.e., as marked by A, B, C, D, respectively). The lithography blocks 301, 302, 303, 304 (and included fiducial structure) are again formed during the metallization processing and are co-planar with and include the same material as the other metallization structures fabricated simultaneously therewith.

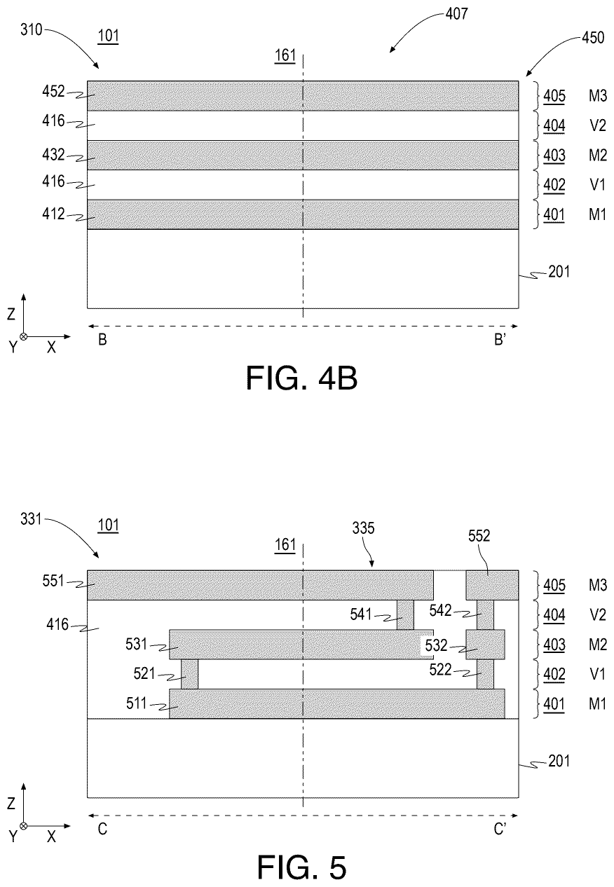

FIG. 4A illustrates a cross-sectional side view of a portion of metallization region 315 of interposer 101, arranged in accordance with at least some implementations of the present disclosure. As shown, FIG. 4A illustrates a portion of metallization region 315 taken at plane A-A′ in FIG. 3. FIG. 4B illustrates a cross-sectional side view of a portion of conductive features 310 crossing seam 161 of interposer 101, arranged in accordance with at least some implementations of the present disclosure. FIG. 4B illustrates a portion of conductive features 310 taken at plane B-B′ in FIG. 3. Notably, metallization region 315 along with metallization regions 316, 317, 318 and conductive features 310 may provide a metallization interconnect or routing structure of interposer 101.

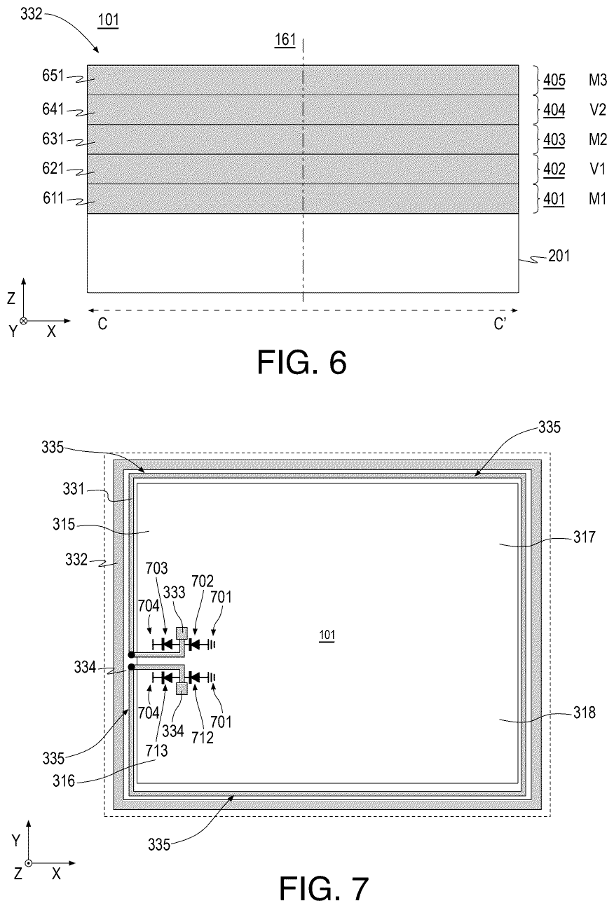

FIG. 5 illustrates a cross-sectional side view of a portion of metallization test feature 331 of interposer 101, arranged in accordance with at least some implementations of the present disclosure. As shown, FIG. 5 illustrates a portion of metallization test feature 331 taken at plane C-C′ in FIG. 3. Notably, metallization test feature 331 may provide a single continuous interconnect route from first contact 333 and second contact 334 of interposer 101. FIG. 6 illustrates a cross-sectional side view of a portion of seal ring 332 of interposer 101, arranged in accordance with at least some implementations of the present disclosure. FIG. 6 illustrates a portion of seal ring 332 taken at plane D-D′ in FIG. 3. As shown, seal ring 332 provides a stack of contiguous metal portions that provide a hermetic seal of the interior of interposer 101.

With reference to FIGS. 4A, 4B, 5, and 6, each includes a component or components implemented in co-planar metallization layers 401, 403, 405 and intervening co-planar via layers 402, 404. Although illustrated with three co-planar metallization layers 401, 403, 405 and two intervening co-planar via layers 402, 404, any number of co-planar metallization layers 401, 403, 405 and intervening co-planar via layers 402, 404. In some embodiments, four, five, six, or more co-planar metallization layers 401, 403, 405 and three, four, five, or more intervening co-planar via layers 402, 404 are used. As shown, co-planar metallization layers 401, 403, 405 may be characterized as metal 1, metal 2, metal 3 (M1, M2, M3) and co-planar via layers 402, 404 may be characterized as via 1, via 2 (V1, V2).

Notably, all components of each layer of metallization regions 315, 316, 317, 318, conductive features 310, metallization test feature 331, and seal ring 332 are fabricated together such that each layer has co-planar components over substrate 201 and such that each layer has components with the same material compositions. For example, metal line 411, conductive feature 412, metal line portion 511, and metal line portion 611 are co-planar with one another in co-planar metallization layer 401 over substrate 201 of interposer 101. Similarly, metal via 421, metal vias 521, 522, and metal line portion 621 are co-planar with one another in co-planar via layer 402 over substrate 201 of interposer 101. Continuing with reference to FIGS. 4A, 4B, 5, and 6, metal line 431, conductive feature 432, metal lines 531, 532, and metal line portion 631 are co-planar with one another in co-planar metallization layer 403, metal via 441, metal vias 541, 542, and metal line portion 641 are co-planar with one another in co-planar via layer 404, and metal line 451, conductive feature 452, metal lines 551, 552, and metal line portion 651 are co-planar with one another in co-planar metallization layer 405, and so on.

Turning to FIG. 4A, interposer 101 includes metallization region 315 having a metallization stack 400 of metallization layers 401, 403, 405 and two intervening co-planar via layers 402, 404 embedded in and separated by insulator material 416. Insulator material 416 may be any suitable insulator or insulators such as silicon oxide. Although illustrated as a single material for the sake of clarity of presentation, insulator material 416 include a stack of insulator materials. Metallization layers 401, 403, 405 include metal lines 411, 431, 451, respectively, which are interconnected by metal vias 421, 441 of via layers 402, 404. Such metal lines 411, 431, 451 and metal vias 421, 441 provide signal and power routing through interposer 101. In some embodiments, IC dies are coupled to a top surface of interposer 101 and metal lines 411, 431, 451 and metal vias 421, 441 provide signal and power routing between the IC dies and/or between the IC dies a package substrate under interposer 101.

For example, interposer 101 may include a metallization network 407 including metallization regions 315, 316, 317, 318 and conductive features 310 (refer to FIGS. 3 and 4B). Metallization network 407 is over substrate 201 and may terminate at top side at an interconnect level for the coupling of IC dies. In some embodiments, each metallization layer 401, 403, 405 of metallization network 407 has a greater thickness than die level metallization levels of the IC dies coupled to interposer 101. Metallization network 407 may include any number of metallization layers 401, 403, 405 and intervening via layer 402, 404. The term metallization level indicates a network of substantially coplanar metal lines or conductive routes. A via level includes a network of substantially coplanar metal vias or conductive plugs that interconnect the metallization levels. In the illustrated example, metallization network 407 has three metallization layers 401, 403, 405 and two intervening via layers 402, 404. However, any number of metallization levels and via levels may be used. In some embodiments, a single metallization level is deployed.

As discussed, conductive features 310 are part of metallization network 407. Turning now to FIG. 4B, interposer 101 includes conductive features 310 having a metallization stack 450 of conductive features 412, 432, 452 at each of metallization layers 401, 403, 405 embedded in and separated by insulator material 416. Although illustrated as being absent any vias, in some embodiments, conductive features 412, 432, 452 may be interconnected by metal vias. Furthermore, in the example of FIG. 4B, each of metallization layers 401, 403, 405 includes one of conductive features 412, 432, 452 such that conductive features 412, 432, 452 are aligned in the z-direction. However, conductive features 412, 432, 452 may be offset with respect to one another in the y-dimension, for example. As discussed, conductive features 412, 432, 452 provide part of metallization network 407 that provides signal and power routing through interposer 101. Furthermore, each of conductive features 412, 432, 452 is co-planar with and has the same material composition as metal lines 411, 431, 451, respectively.

With reference now to FIG. 5, interposer 101 includes metallization test feature 331 surrounding metallization regions 315, 316, 317, 318 (refer to FIG. 3). The operation of metallization test feature 331 is discussed further herein below with respect to FIG. 7. As shown, metallization test feature 331 includes continuous conductive route 335 extending between first contact 333 and second contact 334. Continuous conductive route 335 includes a number of portions or segments including, for example, metal lines 511, 531, 532, 551, 552 and metal vias 521, 522, 541, 542. These components or features of continuous conductive route 335 are designed throughout continuous conductive route 335 or through portions of continuous conductive route 335 to validate the acceptable fabrication of conductive features 310. For example, the components or features of continuous conductive route 335 may be designed to similar critical dimensions and design rules of conductive features 310 to detect unacceptable disconnects or misalignments. Furthermore, the components or features of continuous conductive route 335 may provide a route that will allow for detectable electrical changes (i.e., resistance differences) when such unacceptable disconnects or misalignments occur.

In the context of FIG. 5, continuous conductive route 335 is a continuous serial route in the following order: metal line 551, metal via 541, metal lines 531, metal via 521, metal line portion 511, metal via 521, metal line 532, metal via 542, metal line 552. Such a pattern may serpentine (i.e., in the z-direction) around interposer 101 to provide continuity checks around interposer 101. Furthermore, as shown, metal lines 551, 531, 511 each extend across seam 161. It is advantageous to have a metal lines 551, 531, 511 in each of metallization layers 401, 403, 405 extend across each of seams 161, 162 such that analogous features to conductive features 310 are a part of continuous conductive route 335 for validation of conductive features 310. In some embodiments, each metal line 551, 531, 511 in each of metallization layers 401, 403, 405 at each crossing of seams 161, 162 has the same width (in the x- or y-dimension) as that of conductive features 310 to validate conductive features 310.

Turning to FIG. 6, interposer 101 includes seal ring 332 surrounding metallization test feature 331 and surrounding metallization regions 315, 316, 317, 318 (refer to FIG. 3). As shown, seal ring 332 includes contiguous metal line portions 611, 621, 631, 641, 651 extending entirely around an interior region of interposer 101 such that a wall of metallization regions 315, 316, 317, 318 provides a hermetic seal around a perimeter of interposer 101. For example, substrate 201, metal line portions 611, 621, 631, 641, 651 and an overlying passivation layer (not shown in FIG. 6) provide a hermetic seal of the interior region of interposer 101. As discussed, metal line portion 611 is co-planar with the other features in metallization layer 401, metal line portion 631 is co-planar with the other features in metallization layer 403, and metal line portion 651 is co-planar with the other features in metallization layer 405. Furthermore, metal line portion 621 is co-planar with the other features in via layers 402 and metal line portion 641 is co-planar with the other features in via layers 404. It is noted that via layers 402, 404 may be characterized as via layers despite the presence of metal line portion 621, 641 since the majority of features in via layers 402, 404 are metal vias.

FIG. 7 illustrates an exemplary metallization test feature 331 including contact pads and test circuitry, arranged in accordance with at least some implementations of the present disclosure. As discussed, metallization test feature 331 includes first contact 333 separated from second contact 334, and continuous conductive route 335 coupling first contact 333 and second contact 334. As shown in FIG. 7, first contact 333 and second contact 334 may be deployed as bond pads or bumps that are within an interior of interposer 101. For example, the bond pads or bumps may be over the top metallization layer of metallization regions 315, 316, 317, 318. Furthermore, the bond pads or bumps may offer a wider landing area and/or case of use for coupling test pins or probes to metallization test feature 331.

In some embodiments, the test of metallization test feature 331 is performed at end of line (EOL) to indirectly validate conductive features 310. In some embodiments, metallization test feature 331 is coupled to a supply voltage 704 via diodes 703, 713 and to a ground 701 via diodes 702, 712. In some embodiments, metallization test feature 331 provides single relatively large resistor that surrounds or extends entirely around the interior of interposer 101 including all of metallization regions 315, 316, 317, 318 (refer to FIG. 3). In some embodiments, the test of interposer 101 to validate conductive features 310 measures a resistance in metallization test feature 331 using two test pins or probes that contact first contact 333 and second contact 334 to measure a high and/or low resistance and, if the resultant resistance measurement(s) are within range, the integrity of conductive features 310 is validated.

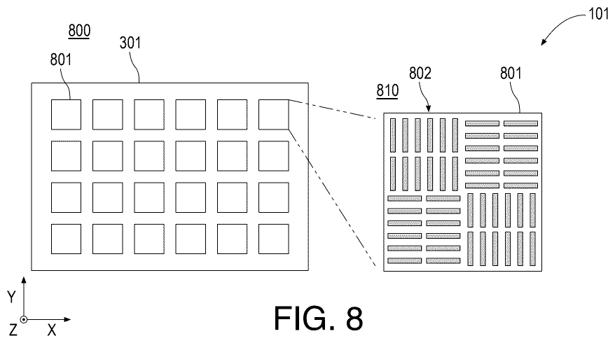

FIG. 8 illustrates an exemplary lithography block 800 including a number of conductive features deployed within metallization regions 315, 316, 317, 318 of interposer 101, arranged in accordance with at least some implementations of the present disclosure. For example, lithography block 800 may be deployed as any of lithography blocks 301, 302, 303, 304. With reference to FIGS. 3 and 4, lithography block 800 is within a metallization layer of metallization regions 315, 316, 317, 318. For example, lithography block 800 may co-planar (in the x-y plane with any of co-planar metallization layers 401, 403, 405. In FIG. 8, a top-down view of lithography block 800 is provided to illustrate the relevant lithography features of lithography block 800.

As shown, lithography block 800 may include any number of features 801 that are conductive due to being co-planar with and being fabricated simultaneously with the metallization features of metallization regions 315, 316, 317, 318 as discussed herein. Features 801 may be sub-blocks of lithography block 800 and, as shown in enlarged view 810, features 801 may include a number of conductive features or sub-features 802 such as an array of vertically aligned and horizontally aligned conductive sub-features 802. It is noted that a wide range of measurement marks, fiducial marks, alignment marks, and so on may be deployed using lithography block 800 as is known in the art. Typically such marks are deployed at the four corners of an exposure field outside of the useable area of the device and are then discarded during segmentation of the device from the wafer.

However, in the context of interposer 101 due to the discussed reticle stitching the central corner of each of fields 115, 116, 117, 118 (i.e., the south-east corner of field 115, the south-west corner of field 116, the north-east corner of field 117, and the north-west corner of field 118) are not available to be discarded as they are part of the active region of interposer 101. Herein, lithography blocks 301, 302, 303, 304 are moved to within the useable or active metallization regions 315, 316, 317, 318 lithographic printing at the cost of removing some metallization features from metallization regions 315, 316, 317, 318. Therefore, lithography block 800 is deployed within metallization regions 315, 316, 317, 318 at some or all vertical layers of the metallization for improved lithography printing and improved reliability in fabricating conductive features 310.

In some embodiments, interposer 101 or an IC die includes lithography block 800 having a fiducial structure, alignment structure, or measurement structure implemented by features 801 such that the fiducial structure, alignment structure, or measurement structure is within one of metallization regions 315, 316, 317, 318 and isolated from the metallization features of metallization regions 315, 316, 317, 318. The fiducial structure, alignment structure, or measurement structure is co-planar with one of co-planar metallization layers 401, 403, 405 or intervening co-planar via layers 402, 404, and has the same material composition as the features of co-planar metallization layers 401, 403, 405 or intervening co-planar via layers 402, 404.

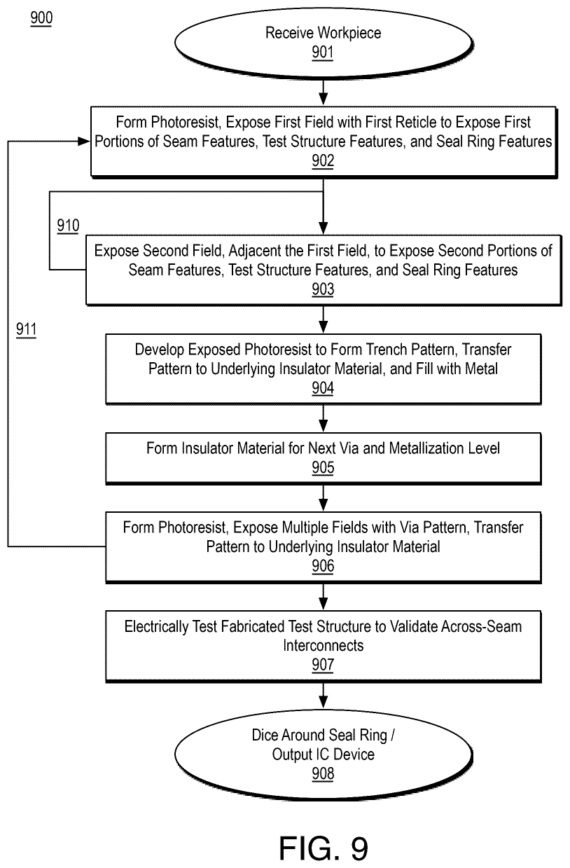

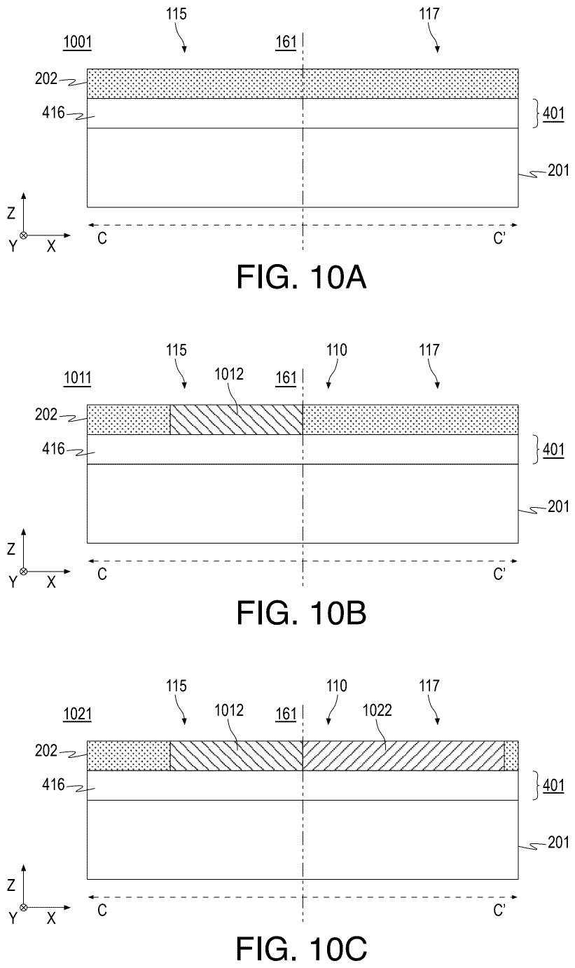

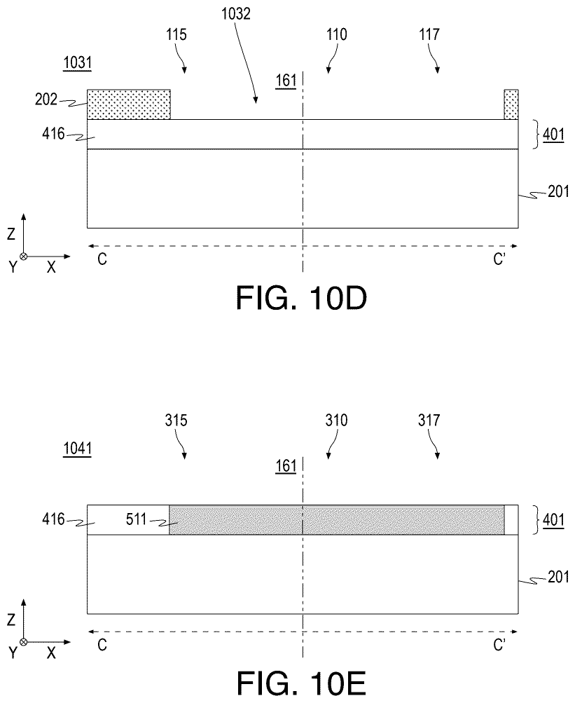

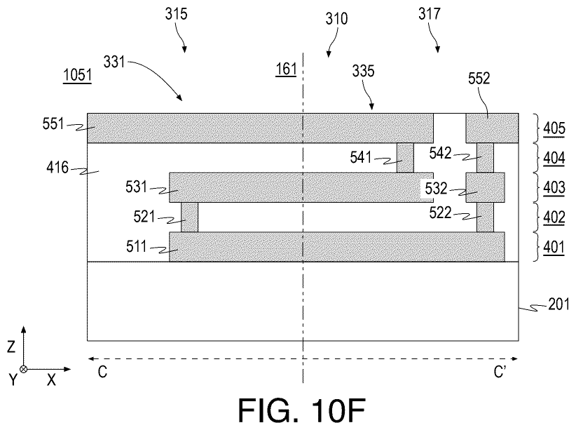

FIG. 9 is a flow diagram illustrating an example process 900 for fabricating an interposer or integrated circuit device having field regions interconnected by cross-seam line features, and a test structure and a seal ring surrounding the field regions fabricated by reticle stitching, arranged in accordance with at least some implementations of the present disclosure. For example, process 900 may be implemented to fabricate device structures illustrated in FIGS. 10A-10F.

FIGS. 10A, 10B, 10C, 10D, 10E, and 10F are views of example interposer or integrated circuit devices as particular fabrication operations of process 900 are performed, arranged in accordance with at least some implementations of the present disclosure.

With reference to FIG. 9, process 900 begins at operation 901, where a workpiece such as a wafer having an underlying dielectric layer is received for processing. In some embodiments, the dielectric layer includes a via pattern for dual damascene patterning of a metallization layer in the dielectric layer. The wafer may include any suitable substrate material. For example, the substrate may include a semiconductor material such as monocrystalline silicon (Si), germanium (Ge), silicon germanium (SiGe), a III-V materials based material (e.g., gallium arsenide (GaAs)), a silicon carbide (SiC), a sapphire (Al₂O₃), or any combination thereof. The wafer may further include, in, on, and/or over the substrate, a device layer and one or more metallization layers. The device layer may include transistors, memory devices, capacitors, resistors, optoelectronic devices, switches, or any other active or passive electronic devices, or portions thereof. The metallization layer(s) may include via layers and metal line layers to interconnect and provide access to the devices.

Processing continues at operation 902, where the wafer is coated with photoresist and a first field is exposed using a first reticle such that features of field 115, a first portion of stitched features or lines 110, the portion(s) of test metallization features 131 in field 115, and the portion(s) of seal ring 132 in field 115 are exposed. The wafer is coated with a photoresist layer for patterning operations. The photoresist layer may include any suitable photoresist such as a positive photoresist material. Notably, during exposure, two edges of field 115 may be exposed to interface with adjacent edges of subsequent fields to be exposed. For example, referring to FIG. 1, features of field 115 at seam 161 are to interface with features of field 116 and features of field 115 at seam 162 are to interface with features of field 117.

FIG. 10A illustrates a cross-sectional view of an interposer or integrated circuit device structure 1001 after the formation of photoresist layer 202 on an insulator material 416 over substrate 201. In FIG. 10A and FIGS. 10B, 10C, 10D, 10E, and 10F, a cross-sectional view of a portion of an interposer or integrated circuit device structure corresponding to the portion of metallization test feature 331 taken at plane C-C′ in FIG. 3 is illustrated (refer to FIG. 5). As will be appreciated the operations of process 900 are performed to simultaneously fabricate all co-planar metallization features of a particular metallization layer as discussed herein.

Substrate 201 may include any material(s) such as monocrystalline silicon, germanium, silicon germanium, a III-V materials based material (e.g., gallium arsenide), a silicon carbide, a sapphire, or the like. A device layer of substrate 201, if employed, may include any devices such as transistors, memory devices, capacitors, resistors, optoelectronic devices, switches, or any other active or passive electronic devices. Such devices are fabricated using known techniques such as lithography, etch, deposition, implant, etc. Insulator material 416 is over substrate 201 and metallization layers and features may be formed in and over insulator material 416 using single damascene or dual damascene techniques. For example, the components of co-planar metallization layer 401 such as conductive feature 412, metal line portion 511, and metal line portion 611 may be simultaneously formed in insulator material 416.

FIG. 10B illustrates an interposer or integrated circuit device structure 1011 similar to interposer or integrated circuit device structure 1001 after patterning a first portion of a line feature that will become line 110, for example. As shown, after the first exposure, region 1012 of photoresist layer 202 is exposed such that region 1012 within field 115 is exposed. In the illustrated example, region 1012 ends at seam 161, however, region 1012 may overlap into field 117 such that there is a greater likelihood of merging region 1012 and a subsequently exposed region. For example, region 1012 may straddle or extend across scam 161.

Returning to FIG. 9, processing continues at operation 903, where a second field, adjacent the first field exposed in operation 902, is exposed using the first reticle or a second reticle such that features of field 116, a second portion of stitched features or lines 110, the portion(s) of test metallization features 131 in field 116, and the portion(s) of seal ring 132 in field 116 are exposed. Notably, operations 902, 903 provide exposure for features of lines 110, test metallization features 131, and seal ring 132 that straddle or cross seam 161. For example, referring to FIG. 1, features of field 116 at seam 161 interface with features of field 115.

As shown with respect to repeated processing arrow 910, the processing discussed with respect to operation 903 is repeated as many times as necessary to expose each field of the interposer or integrated circuit die. In the example of 2×2 field layouts, the processing is repeated twice more to complete the exposure of the adjacent fields.

FIG. 10C illustrates an interposer or integrated circuit device structure 1021 similar to interposer or integrated circuit device structure 1011 after patterning a second portion of the line feature. As shown, after the second exposure, region 1022 of photoresist layer 202 is exposed such that region 1022 within field 117 is exposed. In the illustrated example, region 1022 again ends at seam 161, however, region 1022 may overlap into field 115 such that there is a greater likelihood of merging region 1012 and a subsequently exposed region. For example, region 1022 may straddle or extend across seam 161. In some embodiments, region 1012 and region 1022 extend across seam 161 to form a twice-exposed region. In any event, photoresist layer 202 is fully exposed for the formation of features that extend across seam 161 including lines 110, features of test metallization feature 131, and features of seal ring 132.

Returning to FIG. 9, processing continues at operation 904, where the exposed photoresist is developed to form trench patterns in the photoresist layer, where the pattern in the photoresist layer is transferred to an underlying dielectric material, and the pattern in the dielectric material is filled with a metal or metals to form metal features of the interposer or integrated circuit device. The exposed photoresist may be developed using any suitable technique or techniques that remove the exposed portions of the photoresist and leave unexposed portions of the photoresist. In some embodiments, the exposure of photoresist regions generates photoacids that break down the resist polymer making it soluble in a developer solution. The pattern in the photoresist layer may be transferred to the underlying dielectric material using any suitable technique or techniques such as etch techniques. The metal feature may then be formed using any suitable technique or techniques such as application of a liner material (e.g., titanium nitride, tantalum nitride, or the like), followed by bulk metal fill (e.g., copper fill), which may be followed by planarization techniques. Other metal fill materials and/or processing may be used.

FIG. 10D illustrates an interposer or integrated circuit device structure 1031 similar to interposer or integrated circuit device structure 1021 after developing photoresist layer 202. As shown, after develop processing, photoresist layer 202 includes a trench pattern 1032 in photoresist layer 202. Trench pattern 1032 may include any pattern for formation of any metallization structure discussed herein such as metal line 411, conductive feature 412, metal line portion 511, metal line portion 611, or the like.

FIG. 10E illustrates an interposer or integrated circuit device structure 1041 similar to interposer or integrated circuit device structure 1031 after the removal of photoresist layer 202 (e.g., using ash processing) and formation of metal line portion 511. As shown, metal line portion 511 (and optional liner, not shown) are formed in a trench of insulator material 416. Metal line portion 511 and other co-planar metal features such as metal line 411, conductive feature 412, and metal line portion 611 may be formed using any suitable technique or techniques including electroplating or deposition techniques followed by planarization techniques.

Returning to FIG. 9, processing continues at operation 905, where a next layer of insulator is formed using any suitable technique or techniques such as deposition followed by optional planarization. In some embodiments, the next layer of metal vias and metal features are to be formed in the next layer of insulator. Processing continues at operation 906, where a photoresist layer is formed and multiple via patterns are exposed in the photoresist layer as discussed with respect to operations 902, 903 (i.e., using multi-field patterning). The photoresist is then developed and the via pattern is transferred to the underlying insulator layer. As shown, by repeated processing arrow 911 processing then continues as discussed above with formation of a photoresist layer, and exposure by multiple metallization layer patterns, transfer of the pattern to the underlying insulator material, and metal fill. In such contexts, dual damascene processing may be used to form metal vias and overlying metal lines simultaneously. However, single damascene or other metallization patterning techniques may be used.

FIG. 10F illustrates an interposer or integrated circuit device structure 1051 similar to interposer or integrated circuit device structure 1041 after formation of co-planar via layer 402, co-planar metallization layer 403, co-planar via layer 404, and co-planar metallization layer 405 to form metallization test feature 331 and the other features of interposer 101. Such processing may be repeated any number of times to fabricate a metallization stack having a desired number of co-planar metallization and via layers. In some embodiments, co-planar via layer 402 and co-planar metallization layer 403 are metallized together using dual damascene processing. However, as discussed other techniques may be used.

In some embodiments, process 900 includes exposing a first field 115 of a photoresist layer over a substrate wafer using a first reticle at operation 902. The exposure of field 115 includes exposure of a first portion the metallization pattern of a layer of metallization regions 315, 316, 317, 318, conductive features 310, metallization test feature 331 (e.g., an electrical test pattern), and seal ring 332. Process 900 further includes exposing a second field 116 of the photoresist layer using the first reticle or a second reticle at operation 903. The exposure of field 116 includes exposure of a second portion of the layer of metallization regions 315, 316, 317, 318, conductive features 310, metallization test feature 331 (e.g., a first electrical test pattern), and seal ring 332. Such first and second (and any subsequent exposures) may pattern first, second, and so on portions of the entirety of metallization regions 315, 316, 317, 318, conductive features 310, metallization test feature 331 (e.g., an electrical test pattern), and seal ring 332. Such processing is repeated for via levels and metal levels to form the vertical stack of metallization regions 315, 316, 317, 318, conductive features 310, metallization test feature 331 (e.g., an electrical test pattern), and seal ring 332.

Returning to FIG. 9, processing continues at operation 907, where the edge test metallization structure (e.g., test metallization feature 131) fabricated simultaneously with the other metallization features of the device is electrically tested to validate conductive features 310 (i.e., scam wires) corresponding to the patterns printed at operations 901, 902. The edge test metallization structure may be electrically tested using any suitable technique or techniques. In some embodiments, a resistance of the edge test metallization structure (e.g., test metallization feature 131) is measured using first contact 333 and second contact 334 and the resultant measured resistance is compared to a threshold value. If the resultant measured resistance is greater than the threshold value, the device may pass test and, if the resultant measured resistance is not greater than the threshold value, the device may fail test.

Processing continues at operation 908, where an integrated circuit device such as an interposer or integrated circuit die including reticle stitched metal lines is output. For example, a die or interposer including multiple fields connected by reticle stitched metal lines may be segmented from a remainder of the substrate (i.e., substrate wafer) such that the segmentation is around the seal ring, packaged, and so on, and eventually included in an electronic device. The resultant device (e.g., packaged multichip composite devices or die complexes) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

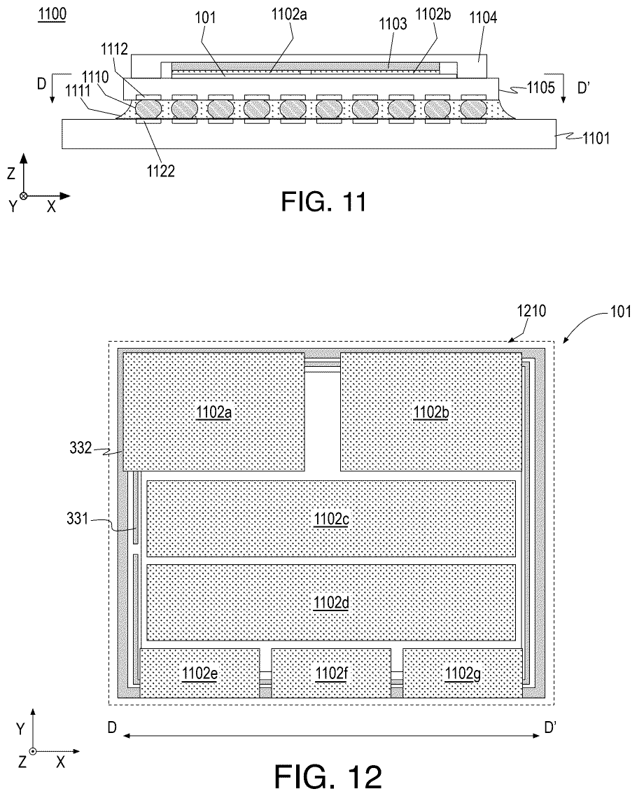

FIG. 11 illustrates an example packaged multichip composite device 1100 including interposer 101 having field regions interconnected by cross-seam line features, and a test structure and a seal ring surrounding the field regions fabricated by reticle stitching, arranged in accordance with at least some implementations of the present disclosure. As shown, packaged multichip composite device 1100 includes interposer 101 coupled to a substrate 1105, which is, in turn, coupled to a microelectronics board 1101. Substrate 1105 may be any suitable substrate such as, a printed circuit board, or the like. Microelectronics board 1101 may include any number of components (not shown) attached to a surface thereof and/or embedded within microelectronics board 1101. Substrate 1105 and microelectronics board 1101 may include a number of dielectric material layers that may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra-low-k dielectrics (dielectric constants less than about 3.6), including, but not limited to, carbon doped dielectrics, fluorine doped dielectrics, porous dielectrics, organic polymeric dielectrics, and the like. Conductive routes within substrate 1105 and microelectronics board 1101 may be a combination of conductive traces and conductive vias extending through the plurality of dielectric material layers. The conductive traces and the conductive vias may be made of any appropriate conductive material, including but not limited to, metals, such as copper, silver, nickel, gold, and aluminum, alloys thereof, and the like.

Interposer 101 is coupled to substrate by interconnects, not shown. Metallization structures 1112 of substrate are coupled to metallization structures 1122 of microelectronics board 1101 using, for example, interconnect structures 1110 such as solder balls or other interconnects. An underfill material 1111, such as an epoxy material, may be disposed between substrate 1105 and microelectronics board 1101. Underfill material 1111 may be dispensed between microelectronics board 1101 and substrate 1105 as a viscous liquid and then hardened with a curing process. Underfill material 1111 may also be a molded underfill material. Underfill material 1111 may provide structural integrity and may prevent contamination, for example.

Also as shown, any number IC dies 1102a, 1102b may be mounted to and electrically coupled to interposer 101. In some embodiments, IC dies 1102a, 1102b are bonded to interposer 101 using a hybrid bonding interface. One or more IC dies 1102a, 1102b are attached over, for example, a passivation layer of interposer 101, which along with seal ring 132 and substrate 201, provide a hermetic seal for the interior of interposer 101. Additional metal routing may extend through substrate 1105 to connect interposer 101 to metallization structures 1112, which may be characterized as package level interconnects. IC dies 1102a, 1102b may be any appropriate devices, including, but not limited to, a microprocessor, an artificial intelligence (AI) die, a die complex, a multichip complex, a chipset, a graphics device, a wireless device, a memory device, an application specific integrated circuit device, artificial intelligence compute devices, cloud computing devices, telecommunication devices, combinations thereof, stacks thereof, or the like.

Multichip composite device 1100 further includes a thermal interface material (TIM) 1103 disposed on a surface of IC dies 1102a, 1102b. TIM 1103 may include any suitable thermal interface material and is in contact with an integrated heat spreader 1104. Integrated heat spreader 1104 includes a planar structure (e.g., in the x-y plane) having a surface on TIM 1103 and extensions projecting from the surface of the planar structure into contact with substrate 1105.

FIG. 12 is a cross-sectional top-down view of multichip composite device 1100 taken at plane D-D′ in FIG. 11. As shown in FIG. 12, IC dies 1102a-g may be a part of an IC die complex 1210 coupled to a surface of interposer 101. As shown, IC die complex 1210 may include any number of IC dies 1102a-g, which may be laterally arrayed on a surface of interposer and/or stacked over the surface of interposer 101. In some embodiments, a passivation layer (not shown) is between IC dies 1102a-g and interposer 101 to provide a portion of the discussed hermetic seal of interposer 101. IC dies 1102a-g may be any appropriate devices, including, but not limited to, microprocessors, chipsets, graphics devices, wireless device, memory devices, application specific integrated circuit devices, artificial intelligence compute devices, cloud computing devices, telecommunication devices, combinations thereof, stacks thereof, or the like.

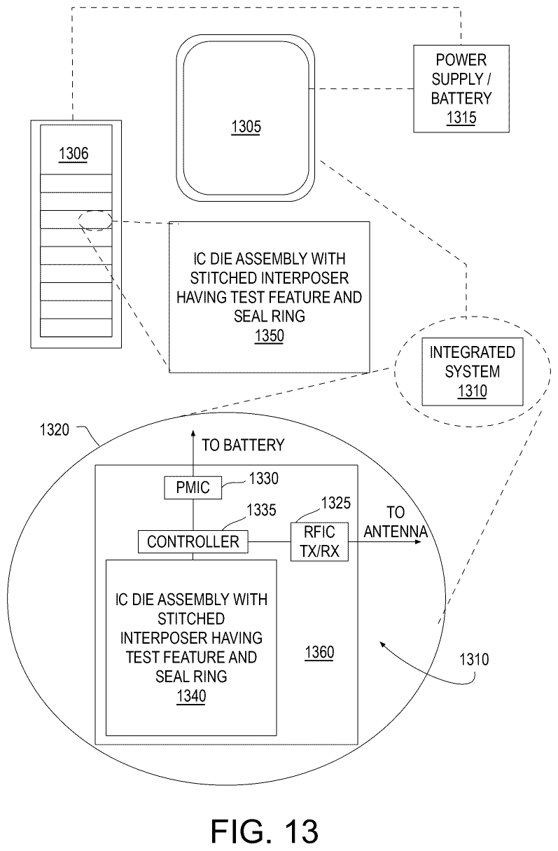

FIG. 13 illustrates exemplary systems employing an IC assembly including a multichip composite device having a stitched interposer or die having a test feature and a seal ring surrounding an interior of the interposer or die, in accordance with some embodiments. The system may be a mobile computing platform 1305 and/or a data server machine 1306, for example. Either may employ a component assembly including a multichip composite device having a stitched interposer or die having a test feature and a seal ring surrounding an interior of the interposer or die as described elsewhere herein. Server machine 1306 may be any commercial server, for example including any number of high-performance computing platforms disposed within a rack and networked together for electronic data processing, which in the exemplary embodiment includes an IC die assembly 1350 with a multichip composite device having a stitched interposer or die having a test feature and a seal ring surrounding an interior of the interposer or die as described elsewhere herein. Mobile computing platform 1305 may be any portable device configured for each of electronic data display, electronic data processing, wireless electronic data transmission, or the like. For example, mobile computing platform 1305 may be any of a tablet, a smart phone, a laptop computer, etc., and may include a display screen (e.g., a capacitive, inductive, resistive, or optical touchscreen), a chip-level or package-level integrated system 1310, and a battery 1315. Although illustrated with respect to mobile computing platform 1305, in other examples, chip-level or package-level integrated system 1310 and a battery 1315 may be implemented in a desktop computing platform, an automotive computing platform, an internet of things platform, or the like. As discussed below, in some examples, the disclosed systems may include a sub-system 1360 such as a system on a chip (SOC) or an integrated system of multiple ICs, which is illustrated with respect to mobile computing platform 1305.

Whether disposed within integrated system 1310 illustrated in expanded view 1320 or as a stand-alone packaged device within data server machine 1306, sub-system 1360 may include memory circuitry and/or processor circuitry 1340 (e.g., RAM, a microprocessor, a multi-core microprocessor, graphics processor, etc.), a power management integrated circuit (PMIC) 1330, a controller 1335, and a radio frequency integrated circuit (RFIC) 1325 (e.g., including a wideband RF transmitter and/or receiver (TX/RX)). As shown, one or more IC dies, such as memory circuitry and/or processor circuitry 1340 may be assembled and implemented such that one or more have a multichip composite device having a stitched interposer or die having a test feature and a seal ring surrounding an interior of the interposer or die as described herein. In some embodiments, RFIC 1325 includes a digital baseband and an analog front end module further comprising a power amplifier on a transmit path and a low noise amplifier on a receive path). Functionally, PMIC 1330 may perform battery power regulation, DC-to-DC conversion, etc., and so has an input coupled to battery 1315, and an output providing a current supply to other functional modules. As further illustrated in FIG. 13, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1340 may provide memory functionality for sub-system 1360, high level control, data processing and the like for sub-system 1360. In alternative implementations, each of the SOC modules may be integrated onto separate ICs coupled to a package substrate, interposer, or board.

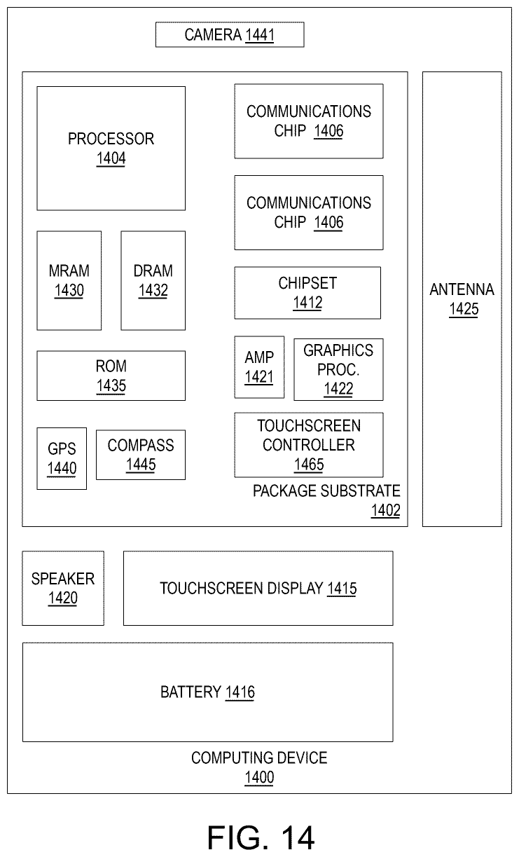

FIG. 14 is a functional block diagram of an electronic computing device 1400, in accordance with some embodiments. For example, device 1400 may, via any suitable component therein, employ a multichip composite device having a stitched interposer or die having a test feature and a seal ring surrounding an interior of the interposer or die in accordance with any embodiments described elsewhere herein. Device 1400 further includes a motherboard or package substrate 1402 hosting a number of components, such as, but not limited to, a processor 1404 (e.g., an applications processor). Processor 1404 may be physically and/or electrically coupled to package substrate 1402. In some examples, processor 1404 is within an IC assembly that includes a multichip composite device having a stitched interposer or die having a test feature and a seal ring surrounding an interior of the interposer or die as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1406 may also be physically and/or electrically coupled to the package substrate 1402. In further implementations, communication chips 1406 may be part of processor 1404. Depending on its applications, computing device 1400 may include other components that may or may not be physically and electrically coupled to package substrate 1402. These other components include, but are not limited to, volatile memory (e.g., DRAM 1432), non-volatile memory (e.g., ROM 1435), flash memory (e.g., NAND or NOR), magnetic memory (MRAM 1430), a graphics processor 1422, a digital signal processor, a crypto processor, a chipset 1412, an antenna 1425, touchscreen display 1415, touchscreen controller 1465, battery 1416, audio codec, video codec, power amplifier 1421, global positioning system (GPS) device 1440, compass 1445, accelerometer, gyroscope, speaker 1420, camera 1441, and mass storage device (such as hard disk drive, solid-state drive (SSD), compact disk (CD), digital versatile disk (DVD), and so forth, or the like.

Communication chips 1406 may enable wireless communications for the transfer of data to and from the computing device 1400. The term “wireless” and its derivatives may be used to describe circuits, devices, systems, methods, techniques, communications channels, etc., that may communicate data through the use of modulated electromagnetic radiation through a non-solidmedium. The term does not imply that the associated devices do not contain any wires, although in some embodiments they might not. Communication chips 1406 may implement any of a number of wireless standards or protocols, including, but not limited to, those described elsewhere herein. As discussed, computing device 1400 may include a plurality of communication chips 1406. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

The following pertains to exemplary embodiments.

In one or more first embodiments, an apparatus comprises a first metallization region and a second metallization region over a substrate, a scam between the first metallization region and the second metallization region, the seam comprising a plurality of conductive features interconnecting the first metallization region and the second metallization region, wherein the first metallization region, the second metallization region, and the conductive features are co-planar over the substrate, and a metallization feature surrounding both the first metallization region and the second metallization region, the metallization feature comprising a first contact separated from a second contact, and a continuous conductive route coupling the first contact and the second contact, the continuous conductive route comprising a first metal portion co-planar with the first metallization region, the second metallization region, and the conductive features.

In one or more second embodiments, further to the first embodiments, the first metallization region and the second metallization region each comprise a plurality of metallization levels, the seam comprises a plurality of interconnect levels, and the continuous conductive route comprises a plurality of metal portion levels, wherein each of the metallization levels, the interconnect levels, and the metal portion levels are co-planar.

In one or more third embodiments, further to the first or second embodiments, each of the metallization levels and the metal portion levels are interconnected by a plurality of co-planar vias, and wherein the continuous conductive route comprises a single route between the first contact and the second contact, the single route comprising the metal portion levels and a first subset of the co-planar vias.

In one or more fourth embodiments, further to the first through third embodiments, the apparatus further comprises a seal ring continuously surrounding the metallization feature, the seal ring comprising contiguous metal portions co-planar with the metallization levels and the co-planar vias.

In one or more fifth embodiments, further to the first through fourth embodiments, each of the metallization levels, the interconnect levels, and the metal portion levels comprises not fewer than two levels.

In one or more sixth embodiments, further to the first through fifth embodiments, the apparatus further comprises a third metallization region and a fourth metallization region over a substrate, wherein the seam extends between the third metallization region and the fourth metallization region, and a second seam orthogonal to the seam, the second seam extending between the third metallization region and the first metallization region and between the second metallization region and the fourth metallization regions, wherein the metallization feature surrounds and extends along a perimeter of the first metallization region, the second metallization region, the third metallization region, and the fourth metallization region.

In one or more seventh embodiments, further to the first through sixth embodiments, the first contact and the second contact are co-planar with the first metallization region, the second metallization region, and the conductive features.

In one or more eighth embodiments, further to the first through seventh embodiments, the apparatus further comprises a fiducial structure within the first metallization region, the fiducial structure comprising a plurality of second conductive features isolated from the first metallization region, wherein the fiducial structure is proximal to the seam relative to a center of the first metallization region.

In one or more ninth embodiments, further to the first through eighth embodiments, the first metal portion, the first metallization region, the second metallization region, and the conductive features comprise the same material composition.

In one or more tenth embodiments, further to the first through ninth embodiments, a first of the conductive features comprises a jog between a first portion of the first of the conductive features and a second portion of the first of the conductive features, the jog extending parallel to the seam between the first metallization region and the second metallization region.

In one or more eleventh embodiments, further to the first through tenth embodiments, the apparatus further comprises an integrated circuit die coupled to the first metallization region, and a power supply coupled to the integrated circuit die.

In one or more twelfth embodiments, an apparatus comprises a first metallization stack and a second metallization stack over a substrate, wherein the first metallization stack comprises a plurality of first metallization levels interconnected by first vias and the second metallization stack comprises a plurality of second metallization levels interconnected by second vias, a scam between the first metallization stack and the second metallization stack, the seam comprising a plurality of wire levels coupling the first metallization stack and the second metallization stack, and a test feature surrounding both the first metallization stack and the second metallization stack, the test feature comprising a first contact separated from a second contact, and a continuous conductive route coupling the first contact and the second contact, the continuous conductive route comprising a plurality of metal portion levels interconnected by third vias, wherein each of the first metallization levels, the second metallization levels, the wire levels, and the metal portion levels are co-planar, and wherein the first vias, the second vias, and the third vias are co-planar.

In one or more thirteenth embodiments, further to the twelfth embodiments, the apparatus further comprises a seal ring continuously surrounding the test feature, the seal ring comprising contiguous metal portions co-planar with the first metallization levels and the first vias.

In one or more fourteenth embodiments, further to the twelfth or thirteenth embodiments, the apparatus further comprises a third metallization stack and a fourth metallization stack over the substrate, wherein the seam extends between the third metallization stack and the fourth metallization stack, and a second seam orthogonal to the seam, the second seam extending between the first metallization stack and the third metallization stack and between the second metallization stack and the fourth metallization stack, wherein the test feature surrounds and extends along a perimeter of the first metallization stack, the second metallization stack, the third metallization stack, and the fourth metallization stack.

In one or more fifteenth embodiments, further to the twelfth through fourteenth embodiments, the apparatus further comprises a fiducial structure within the first metallization stack, the fiducial structure comprising a plurality of second conductive features isolated from the first metallization stack, wherein the fiducial structure is proximal to the seam relative to a center of the first metallization stack.

In one or more sixteenth embodiments, further to the twelfth through fifteenth embodiments, the apparatus further comprises an integrated circuit die coupled to the first metallization stack, and a power supply coupled to the integrated circuit die.

In one or more seventeenth embodiments, a method comprising exposing a first field of a photoresist layer over a substrate wafer using a first reticle, said exposing the first field to expose a first metallization pattern, a first seam wire pattern, and a first electrical test pattern, exposing a second field of the photoresist layer using the first reticle or a second reticle, said exposing the second field to expose a second metallization pattern, a second seam wire pattern contiguous with the first seam wire pattern, and a second electrical test pattern contiguous with the first electrical test pattern, forming metallization structures corresponding to the first metallization pattern, the first seam wire pattern, the first electrical test pattern, the second metallization pattern, the second seam wire pattern, and the second electrical test pattern, and electrically testing an edge test metallization structure corresponding to the first electrical test pattern and the second electrical test pattern to validate seam wires corresponding to the first seam wire pattern and the second seam wire pattern.

In one or more eighteenth embodiments, further to the seventeenth embodiments, said exposing the first field comprises alignment using a fiducial structure within the first field and proximal to the second field, wherein said forming the metallization structures comprises forming a fiducial structure metallization within a first metallization region corresponding to the first metallization pattern.

In one or more nineteenth embodiments, further to the seventeenth or eighteenth embodiments, said exposing the first field comprises alignment using a second fiducial structure across the first electrical test pattern from the fiducial structure.

In one or more twentieth embodiments, further to the seventeenth through nineteenth embodiments, said exposing the first field further exposes a first seal ring pattern across the first electrical test pattern from the first metallization pattern.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first metallization region and a second metallization region over a substrate;
a seam between the first metallization region and the second metallization region, the seam comprising a plurality of conductive features interconnecting the first metallization region and the second metallization region, wherein the first metallization region, the second metallization region, and the conductive features are co-planar over the substrate; and
a metallization feature surrounding both the first metallization region and the second metallization region, the metallization feature comprising a first contact separated from a second contact, and a continuous conductive route coupling the first contact and the second contact, the continuous conductive route comprising a first metal portion co-planar with the first metallization region, the second metallization region, and the conductive features.

2. The apparatus of claim 1, wherein the first metallization region and the second metallization region each comprise a plurality of metallization levels, the seam comprises a plurality of interconnect levels, and the continuous conductive route comprises a plurality of metal portion levels, wherein each of the metallization levels, the interconnect levels, and the metal portion levels are co-planar.

3. The apparatus of claim 2, wherein each of the metallization levels and the metal portion levels are interconnected by a plurality of co-planar vias, and wherein the continuous conductive route comprises a single route between the first contact and the second contact, the single route comprising the metal portion levels and a first subset of the co-planar vias.

4. The apparatus of claim 3, further comprising:
a seal ring continuously surrounding the metallization feature, the seal ring comprising contiguous metal portions co-planar with the metallization levels and the co-planar vias.

5. The apparatus of claim 2, wherein each of the metallization levels, the interconnect levels, and the metal portion levels comprises not fewer than two levels.

6. The apparatus of claim 1, further comprising:
a third metallization region and a fourth metallization region over a substrate, wherein the seam extends between the third metallization region and the fourth metallization region; and
a second seam orthogonal to the seam, the second seam extending between the third metallization region and the first metallization region and between the second metallization region and the fourth metallization regions, wherein the metallization feature surrounds and extends along a perimeter of the first metallization region, the second metallization region, the third metallization region, and the fourth metallization region.

7. The apparatus of claim 1, wherein the first contact and the second contact are co-planar with the first metallization region, the second metallization region, and the conductive features.

8. The apparatus of claim 1, further comprising:
a fiducial structure within the first metallization region, the fiducial structure comprising a plurality of second conductive features isolated from the first metallization region, wherein the fiducial structure is proximal to the seam relative to a center of the first metallization region.

9. The apparatus of claim 1, wherein the first metal portion, the first metallization region, the second metallization region, and the conductive features comprise the same material composition.

10. The apparatus of claim 1, wherein a first of the conductive features comprises a jog between a first portion of the first of the conductive features and a second portion of the first of the conductive features, the jog extending parallel to the seam between the first metallization region and the second metallization region.

11. The apparatus of claim 1, further comprising:
an integrated circuit die coupled to the first metallization region; and
a power supply coupled to the integrated circuit die.

12. An apparatus, comprising:
a first metallization stack and a second metallization stack over a substrate, wherein the first metallization stack comprises a plurality of first metallization levels interconnected by first vias and the second metallization stack comprises a plurality of second metallization levels interconnected by second vias;
a seam between the first metallization stack and the second metallization stack, the seam comprising a plurality of wire levels coupling the first metallization stack and the second metallization stack; and
a test feature surrounding both the first metallization stack and the second metallization stack, the test feature comprising a first contact separated from a second contact, and a continuous conductive route coupling the first contact and the second contact, the continuous conductive route comprising a plurality of metal portion levels interconnected by third vias, wherein each of the first metallization levels, the second metallization levels, the wire levels, and the metal portion levels are co-planar, and wherein the first vias, the second vias, and the third vias are co-planar.

13. The apparatus of claim 12, further comprising:
a seal ring continuously surrounding the test feature, the seal ring comprising contiguous metal portions co-planar with the first metallization levels and the first vias.

14. The apparatus of claim 12, further comprising:
a third metallization stack and a fourth metallization stack over the substrate, wherein the seam extends between the third metallization stack and the fourth metallization stack; and
a second seam orthogonal to the seam, the second seam extending between the first metallization stack and the third metallization stack and between the second metallization stack and the fourth metallization stack, wherein the test feature surrounds and extends along a perimeter of the first metallization stack, the second metallization stack, the third metallization stack, and the fourth metallization stack.

15. The apparatus of claim 12, further comprising:
a fiducial structure within the first metallization stack, the fiducial structure comprising a plurality of second conductive features isolated from the first metallization stack, wherein the fiducial structure is proximal to the seam relative to a center of the first metallization stack.

16. The apparatus of claim 12, further comprising:
an integrated circuit die coupled to the first metallization stack; and
a power supply coupled to the integrated circuit die.

17. A method, comprising:
exposing a first field of a photoresist layer over a substrate wafer using a first reticle, said exposing the first field to expose a first metallization pattern, a first seam wire pattern, and a first electrical test pattern;
exposing a second field of the photoresist layer using the first reticle or a second reticle, said exposing the second field to expose a second metallization pattern, a second seam wire pattern contiguous with the first seam wire pattern, and a second electrical test pattern contiguous with the first electrical test pattern;
forming metallization structures corresponding to the first metallization pattern, the first seam wire pattern, the first electrical test pattern, the second metallization pattern, the second seam wire pattern, and the second electrical test pattern; and
electrically testing an edge test metallization structure corresponding to the first electrical test pattern and the second electrical test pattern to validate seam wires corresponding to the first seam wire pattern and the second seam wire pattern.

18. The method of claim 17, wherein said exposing the first field comprises alignment using a fiducial structure within the first field and proximal to the second field, wherein said forming the metallization structures comprises forming a fiducial structure metallization within a first metallization region corresponding to the first metallization pattern.

19. The method of claim 18, wherein said exposing the first field comprises alignment using a second fiducial structure across the first electrical test pattern from the fiducial structure.

20. The method of claim 17, wherein said exposing the first field further exposes a first seal ring pattern across the first electrical test pattern from the first metallization pattern.
